(19) United States
(12) Patent Application Publication
(10) Pub. No.: US 2011/0157802 A1
(43) Pub. Date: Jun. 30, 2011

(54) PORTABLE ELECTRONIC DEVICE WITH ROTATING DISPLAY

(75) Inventor: JIAN-HUI LI, Shenzhen City (CN)

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/826,807

(22) Filed: Jun. 30, 2010

(30) Foreign Application Priority Data
Dec. 30, 2009 (CN) 200910312750.1

(51) Int. Cl. H05K 5/02

(52) U.S. Cl. 361/679.02; 361/679.01

(57) ABSTRACT

A portable electronic device includes a first body, a second body, and two pivot members. The first body defines two holes. A first axis is defined along the centerlines of the holes. The second body defines a hole, a second axis is defined the center of the hole. Each of the pivot members includes a first connecting portion and a second connecting portion extending from two ends thereof, each first connecting portion is rotatably assembled in the corresponding holes, each second connecting portion is rotatably assembled in the hole. The second body rotates around the first axis, and rotates around the second axis.

### BACKGROUND

1. Technical Field

The present disclosure generally relates to portable electronic devices, and particularly, to a portable electronic device having a rotating display.

2. Description of Related Art

Typical portable electronic devices such as mobile phones especially bar type mobile phones include a main body, a display and a keyboard all on one face of the main body. However, the keys occupy a large area of the main body, so the dimensions of the display may be limited to accommodate the space for the keyboard. Therefore, it may be difficult for users to view the information on the display due to its limited size.

Therefore, there is a room for improvement within the art.

### BRIEF DESCRIPTION OF THE DRAWINGS

Many aspects of the portable electronic device with rotating display can be better understood with reference to the following drawings. The components in the drawings are not necessarily to scale, the emphasis instead being placed upon clearly illustrating the portable electronic device with rotating display. Moreover, in the drawings, like reference numerals designate corresponding parts out the several views.

FIG. 1 is an exploded, isometric view of an exemplary portable electronic device.

FIG. 2 is an isometric view of a second body of the portable electronic device shown in FIG. 1, but viewed from another angle.

FIG. 3 is a block circuit diagram view of a sensing circuit of the electronic device.

FIG. 4 is an assembled, isometric view of the portable electronic device shown in FIG. 1.

FIG. 5 is an isometric view of the portable electronic device in an open position.

FIG. 6 is an isometric view of the portable electronic device in a closed position.

FIG. 7 is an alternative embodiment of the portable electronic device.

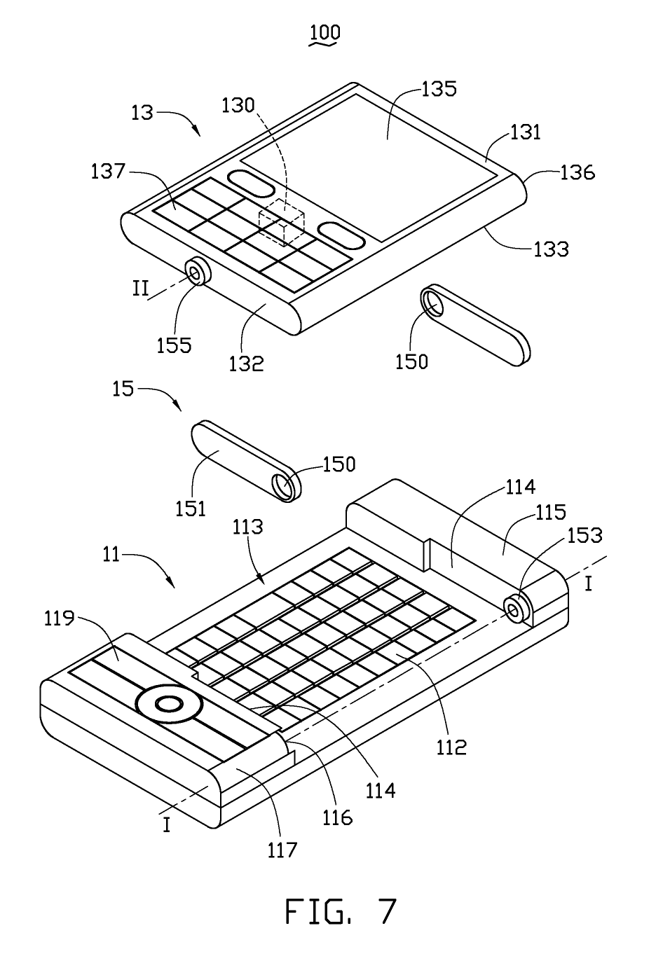

### DETAILED DESCRIPTION

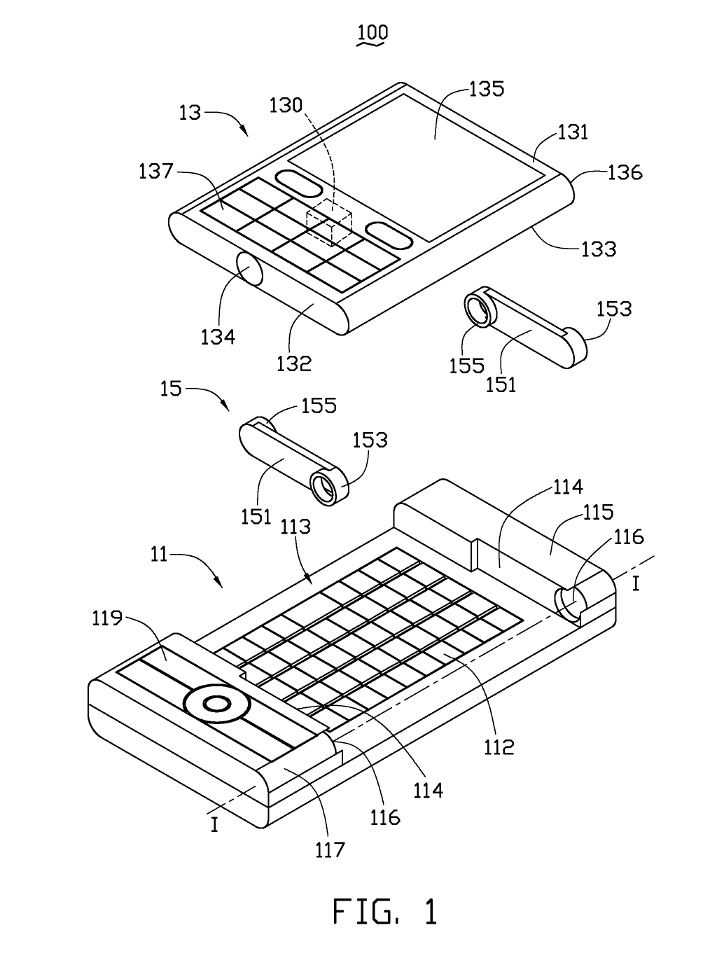

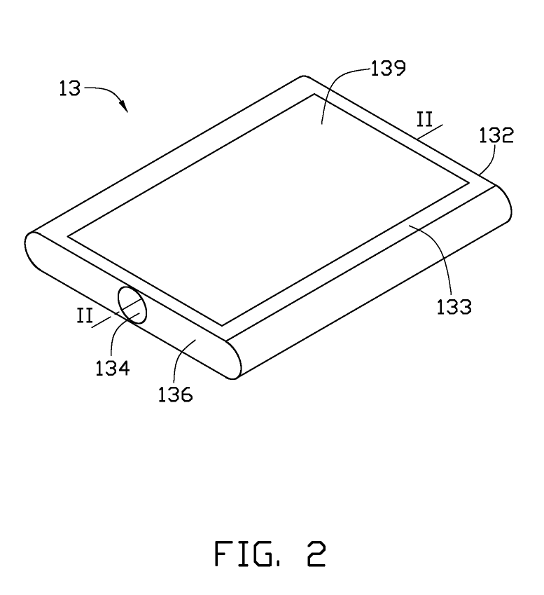

FIG. 1 and FIG. 2 show an exemplary embodiment of a portable electronic device 100, such as a mobile phone or a personal digital assistant for example. The portable electronic device 100 includes a first body 11, a second body 13, and two pivot members 15. The second body 13 is rotatably attached to the first body 11 by the pivot members 15.

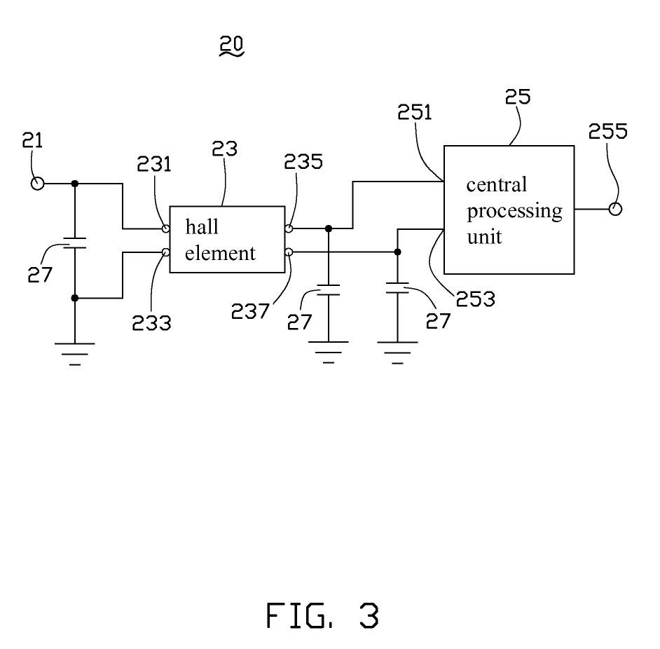

The first body 11 defines a receiving area 113 for accommodating the second body 13. Thus, a first end 115 and a second end 117 are located at opposite sides of the receiving area 113. A keyboard 112 on a bottom surface of the receiving area 113 allows for e.g. keying text messages. The first end 115 and the second end 117 respectively define a groove 114 and a hole 116 for receiving the pivot members 15. The groove 114 communicates with the receiving area 113. The second end 117 includes a function keys 119 disposed thereon. A first axis I-I is defined along the centerlines of the holes 116. The second body 13 can rotate around the first axis I-I from 0 degree to 180 degrees. A circuit board (not shown) is received in the first body 11, and includes a sensing circuit 20 in FIG. 3.

The second body 13 includes a first surface 131, an opposite second surface 133, a first sidewall 132, and an opposite second sidewall 136. The first surface 131 includes a first display 135 and a key pad 137 disposed thereon. The dimensions of the first surface 131 may be limited because of the key pad 137 area of the first surface 131. Therefore, the first surface 131 is configured for displaying information requiring only limited amounts of space, such as the time. The second surface 133 includes a second display 139 disposed thereon. The second display 139 is larger than the first display 135, thus, the second display 139 can display text messages, movies, and other information requiring more space. A hole 134 is defined in the first sidewall 132 and the second sidewall 136 of the second body 13. A second axis II-II is defined along the centerlines of the holes 134. The second body 13 can rotate around the second axis II-II from 0 degree to 360 degrees for enabling the second body 13 to display the first display 135 or the second display 139.

The second body 13 further includes a magnet 130 disposed therein. A first pole of the magnet 130 faces the first surface 131, and a second pole of the magnet 130 faces the second surface 133.

Each of the pivot members 15 may be a hollow bar-shaped including a first connecting portion 153 in a first end of the pivot member 15 and a second connecting portion 155 in a second end of the pivot member 15. The first and second ends of the pivot member 15 extending from opposite surfaces of each pivot member 15. The first connecting portion 153 and the second connecting portion 155 can be rotatably assembled in the corresponding holes 116 and holes 134.

Referring to FIG. 3, the sensing circuit 20 includes a power source 21, a hall element 23, a central processing unit (CPU) 25, and a plurality of filter capacitors 27. The hall element 23 includes a first input terminal 231, a grounding terminal 233, a first output terminal 235, and a second output terminal 237. The central processing unit 25 includes a second input terminal 251, a third input terminal 253, and a third output terminal 255. The power source 21 electronically connects the first input terminal 231. The power source 21 connects a ground by one of the filter capacitors 27. The first output terminal 235 electronically connects the second input terminal 251. The second output terminal 237 electronically connects the third input terminal 253. The first output terminal 235 and the second output terminal 237 respectively connect the ground by one of the filter capacitors 27. The third output terminal 255 electronically connects the second body 13.

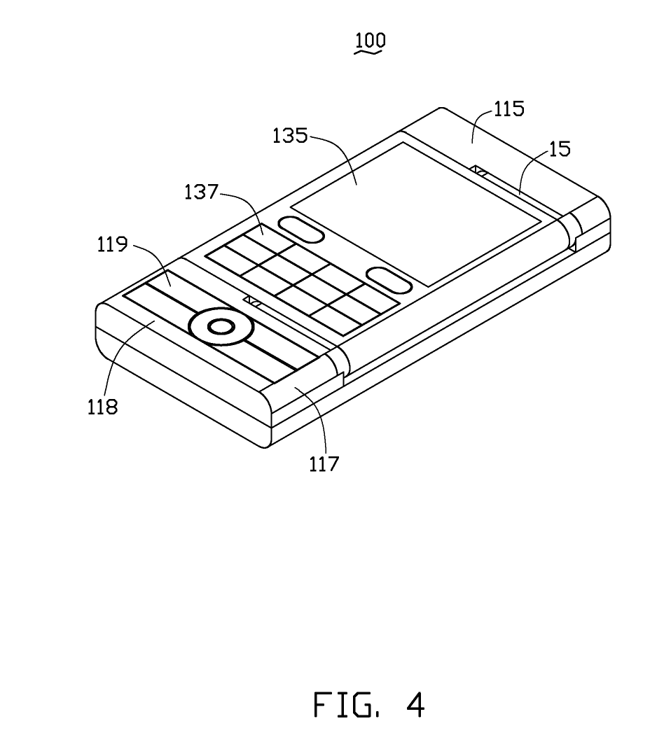

Referring to FIG. 4, in assembly, each second connecting portion 155 is inserted into corresponding hole 134. Thus, the pivot members 15 are rotatably assembled to the second body 13. Each first connecting portion 153 is inserted into corresponding hole 116. Thus, the pivot members 15 are rotatably assembled to the first body 11.

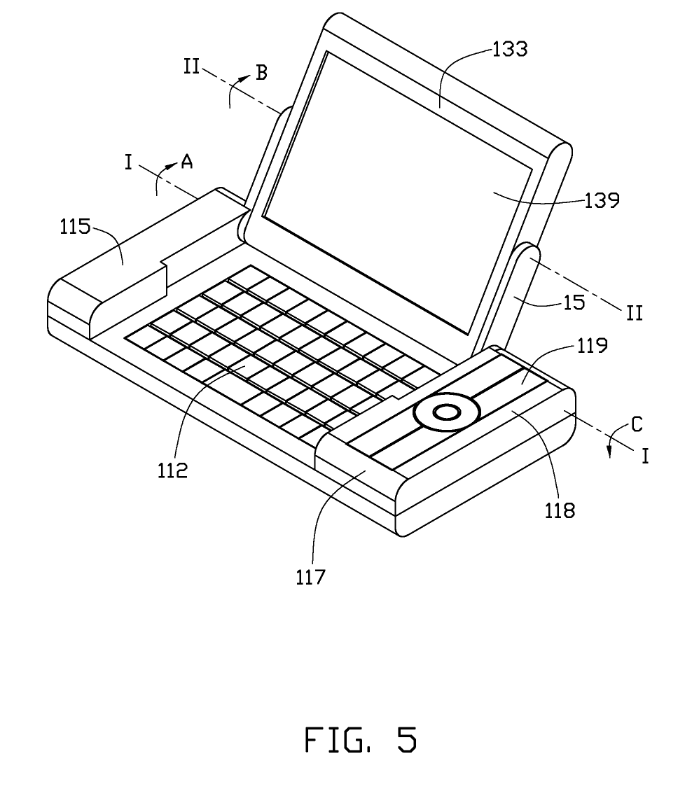

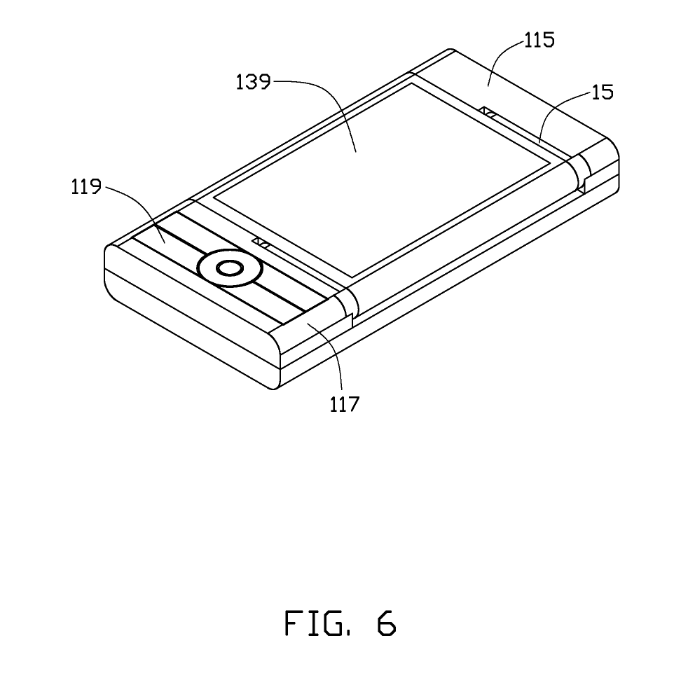

Referring to FIGS. 5 and 6, in a closed position, the second body 13 is received in the receiving area 113, and the first display 135 is exposed. When users want to view the second display 139, or to input text messages for example, the second body 13 is rotated around the first axis I-I as shown by arrow A. Then the second body 13 is latched on the first body 11 by a friction fit connection between the first connecting portion 153 and the first body 11. The second display 139 is approximately perpendicular to the first body 11, and the keyboard 112 is exposed. Thus, the portable electronic device 100 can be used as a notebook-type computer. If users want to watch movies from the second display 139 when the portable electronic device 100 is in a bar-shaped position, the second body 13 is rotated around the second axis II-II as shown by arrow B. Then, the second body 13 is rotated around the first axis I-I as shown by arrow C, thus, the second body 13 is received in the receiving area 113, and the second display 139 is viewable from the first body 11.

Working processes of the sensing circuit 20 may include following steps: when the first display 135 is used as shown in FIG. 4, the second surface 133 approaches to the sensing circuit 20, the hall element 23 detects that the magnetic field direction of the magnet 130 is changed from the first pole to the second pole, and the second pole approaches the sensing circuit 20. The first output terminal 235 transmits a low level voltage signal and the second output terminal 237 transmits a high level voltage signal. The central processing unit 25 receives the signals and turns off the second display 139 and turns on the first display 135.

When the second display 139 is used as shown in FIG. 5, the first surface 131 and the second surface 133 are apart from the sensing circuit 20. The first output terminal 235 transmits a high level voltage signal, the second output terminal 237 transmits a high level voltage signal. The central processing unit 25 receives the high level voltage to turn on the first display 135 and the second display 139.

When the second display 139 is used as shown in FIG. 6, and as the first surface 131 contacts the sensing circuit 20, the hall element 23 detects that the magnetic field direction of the magnet 130 is changed from the first pole to the second pole, and the first pole approaches the sensing circuit 20. The first output terminal 235 transmits a high level voltage, the second output terminal 237 transmits a low level voltage. The central processing unit 25 receives the low level voltage signal and the high level voltage signal to turn off the first display 135 and turn on the second display 139.

In an alternative embodiment, two first connecting portions 153 and two second connecting portions 155 can be respectively positioned on the first body 11 and the second body 13. Correspondingly, each pivot member 15 defines two receiving holes 150 at two ends thereof for rotatably receiving the first connecting portion 153 and the second connecting portion 155. A first axis I-I is defined along the centerlines of the first connecting portions 153. The second body 13 can rotate around the first axis I-I. A second axis II-II is defined along the centerlines of the second connecting portions 155. The second body 13 can rotate around the second axis II-II.

It is to be understood, however, that even through numerous characteristics and advantages of the present disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A portable electronic device, comprising:
a first body defining two holes, a first axis defined along the centerlines of the holes;
a second body defining two holes, a second axis defined along the centerlines of the second body holes; and
two pivot members, each of the pivot members comprising a first connecting portion extending from a first end of each pivot member and a second connecting portion extending from a second end of each pivot member, each first connecting portion rotatably assembled in a corresponding holes, each second connecting portion rotatably assembled in a corresponding second body hole,
wherein the second body rotates around the first axis from 0 degree to 180 degrees, and rotates around the second axis from 0 degree to 360 degrees.

2. The portable electronic device as claimed in claim 1, wherein the first body defines a receiving area for receiving the second body.

3. The portable electronic device as claimed in claim 2, wherein the pivot members are hollow, the first connecting portion and the second connecting portion are positioned at two ends of each pivot member, and the first and second connecting portions extend from opposite surfaces of each pivot member.

4. The portable electronic device as claimed in claim 3, wherein the receiving area comprises two grooves defined in opposite sidewalls thereof, the pivot members are received in the grooves, each hole is defined in a corresponding groove.

5. The portable electronic device as claimed in claim 4, wherein a bottom of the receiving area comprises a keyboard, the second body comprises a first display and a second display disposed on opposite sides thereof, when the second body is received in the receiving area, the first display or the second display faces the keyboard.

6. The portable electronic device as claimed in claim 1, wherein the second body comprises a magnet disposed therein, a first pole and a second pole of the magnet face opposite surfaces of the second body, the first body containing a sensing circuit.

7. The portable electronic device as claimed in claim 6, wherein the sensing circuit comprises a power source, a hall element, a central processing unit; the hall element comprises a first input terminal electronically connecting the power source, a grounding terminal, a first output terminal, and a second output terminal; the central processing unit comprises a second input terminal, a third input terminal, and a third output terminal, the first output terminal electronically connects the second input terminal, the second output terminal electronically connects the third input terminal, the third output terminal electronically connects the second body.

8. A portable electronic device, comprising:
a first body comprising two first connecting portions positioned at two ends thereof, a first axis defined along the centerlines of the of the first connecting portions;
a second body comprising two second connecting portions positioned at two ends thereof, a second axis defined along the centerlines of the second connecting portions; and
two pivot members, each of the pivot members defining two receiving holes at two ends thereof, the first connecting portions and the second connecting portions rotatably assembled in the corresponding receiving holes,
wherein the second body rotates around the first axis from 0 degree to 180 degrees, and rotates around the second axis from 0 degree to 360 degrees.

9. The portable electronic device as claimed in claim 8, wherein the first body defines a receiving area for receiving the second body.

10. The portable electronic device as claimed in claim 9, wherein a bottom of the receiving area comprises an inputting key portion, the second body comprises a first display and a second display disposed on two opposite sides thereof, when the second body is received in the receiving area, the first display or the second display faces the inputting key portion.

11. The portable electronic device as claimed in claim 8, wherein the second body comprises a magnet perpendicularly disposed therein, a first pole and a second pole of the magnet face two opposite surface of the second body, the first body comprises a sensing circuit.

12. The portable electronic device as claimed in claim 11, wherein the sensing circuit comprises a power source, a hall element, a central processing unit; the hall element comprises a first input terminal electronically connecting the power source, a grounding terminal, a first output terminal, and a second output terminal; the central processing unit comprises a second input terminal, a third input terminal, and a third output terminal, the first output terminal electronically connects the second input terminal, the second output terminal electronically connects the third input terminal, the third output terminal electronically connects the second body.
